(19) United States
(12) Patent Application Publication
(10) Pub. No.: US 2013/0033953 A1
(43) Pub. Date: Feb. 7, 2013

(54) COMPUTER MOTHERBOARD AND VOLTAGE ADJUSTMENT CIRCUIT THEREOF

(71) Applicants: TING GE, Shenzhen City (CN); YING-BIN FU, Shenzhen City (CN); YA-JUN PAN, Shenzhen City (CN)

(72) Inventors: TING GE, Shenzhen City (CN); YING-BIN FU, Shenzhen City (CN); YA-JUN PAN, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/553,833

(22) Filed: Jul. 20, 2012

(30) Foreign Application Priority Data
Aug. 3, 2011 (CN) 201110220770.3

(51) Int. Cl. G11C 5/14

(52) U.S. Cl. 365/226

(57) ABSTRACT

A voltage adjustment circuit includes a south bridge, a complex programmable logic device (CPLD), a power supply unit, a voltage conversion unit, and a resistance unit. The south bridge detects a type of a number of dynamic random access memories (DRAMs), and outputs a corresponding signal according to a detected result of the type of the DRAMs. The CPLD is connected to the south bridge to receive the signal, and outputs a corresponding control signal according to the signal. The voltage conversion unit is connected to the power supply unit and the DRAMs, and converts voltage output from the power supply unit into a stable voltage. The resistance unit is connected to the CPLD and the voltage conversion unit, and provides different resistance according to the control signal received from the CPLD, to adjust the voltage output from the voltage conversion unit to an operation voltage of the DRAMs.

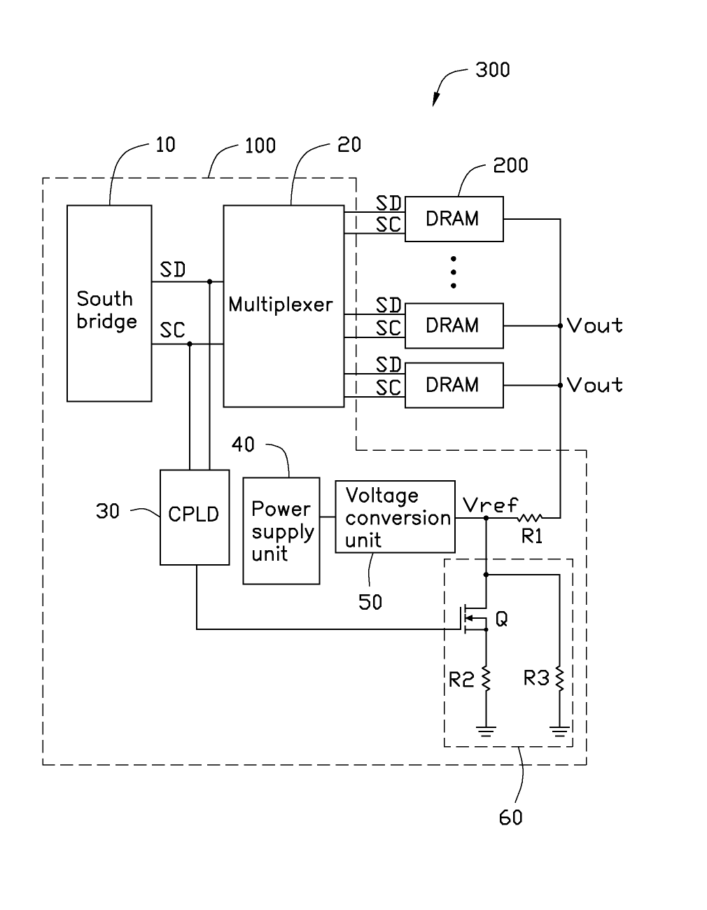

### BACKGROUND

1. Technical Field

The present disclosure relates to computer motherboards, and more particularly to a computer motherboard with a voltage adjustment circuit.

2. Description of Related Art

With types and capacity of the dynamic random access memory (DRAM) continuously changing and progressing, operation voltages of DRAMs also change. Specifically, the operation voltage of double data rate (DDR) DRAM is 2.5 volts (V), the operation voltage of DDR2 DRAM is 1.8V, and the operation voltage of DDR3 DRAM is 1.5V. For a computer motherboard to be able to accommodate different types of DRAMs, the motherboard should be able to provide different operation voltages. Currently, a DDR integrated circuit (IC) chip with a system management bus is used to provide operation voltages to DRAMs, according to the types of the DRAMs. However, the DDR IC chip is costly.

### BRIEF DESCRIPTION OF THE DRAWING

Many aspects of the embodiments can be better understood with reference to the following drawing. The components in the drawing are not necessarily drawn to scale, the emphasis instead being placed upon clearly illustrating the principles of the present embodiments. Moreover, in the drawing, like reference numerals designate corresponding parts throughout the view.

The figure is a circuit diagram of a voltage adjustment circuit in accordance with an exemplary embodiment of the present disclosure, showing the voltage adjustment circuit positioned on a computer motherboard and connected to a plurality of dynamic random access memories.

### DETAILED DESCRIPTION

The disclosure, including the accompanying drawing, is illustrated by way of examples and not by way of limitation. It should be noted that references to “an” or “one” embodiment in this disclosure are not necessarily to the same embodiment, and such references mean at least one.

The figure, is an exemplary embodiment of a voltage adjustment circuit 100 used to provide voltage to a plurality of dynamic random access memories (DRAMs) 200 assembled on a computer motherboard 300, according to the type of the DRAMs 200. The voltage adjustment circuit 100 includes a south bridge 10, a multiplexer 20, a complex programmable logic device (CPLD) 30, a power supply unit 40, a voltage conversion unit 50, a resistance unit 60, and a resistor R1.

The south bridge 10 is connected to the CPLD 30, and connected to the DRAMs 200 through the multiplexer 20. The voltage conversion unit 50 is connected to the power supply unit 40, and connected to the DRAMs 200 through the resistor R1. The resistance unit 60 is connected to the CPLD 30 and the voltage conversion unit 50.

The south bridge 10 is used to detect a type of the DRAMs 200, and output a corresponding signal to the CPLD 30 according to the detected result of the type of the DRAMs 200. It may be understood that the types of the DRAMs 200 include double data rate (DDR) DRAMs requiring 2.5 volt (V) operation voltage, and DDR2 DRAMs requiring 1.5V operation voltage. The CPLD 30 is used to output a corresponding control signal to the resistance unit 60, according to the signal received from the south bridge 10. The multiplexer 20 is used to assist the south bridge 10 to communicate with the DRAMs 200. The power supply unit 40 is used to supply voltage to the voltage conversion unit 50. The voltage conversion unit 50 is used to convert voltage output from the power supply unit 40 into a stable voltage Vref. The resistance unit 60 is used to provide different resistances according to the control signal received from the CPLD 30. The relationship of the voltage Vref output from the voltage conversion unit 50, a voltage Vout input into the DRAMs 200, a resistance r of the resistance unit 60, and a resistance r1 of the resistor R1 is Vout=Vref(1+r1/r). When the voltage Vref and the resistance r1 are constant, and the resistance r is increased, then the voltage Vout is decreased.

In one embodiment, the south bridge 10 includes a data pin SD and a clock pin SC. Each DRAM 200 includes a data pin SD and a clock pin SC. The data pins SD and the clock pins SC of the south bridge 10 and each DRAM 200 are connected to the multiplexer 20. The south bridge 10 detects the type of the DRAMs 200, according to information received from the data pins SD and the clock pins SC of the DRAMs 200. The DRAMs 200 are inserted into dual inline memory module (DIMM) slots (not shown) of the computer motherboard 300, and connected to the multiplexer 20 through the DIMM slots. The voltage conversion unit 50 is a buck circuit. The resistance unit 60 includes an electronic switch Q and two resistors R2 and R3. A control terminal of the electronic switch Q is connected to the CPLD 30 to receive the control signal. A power terminal of the electronic switch Q is connected to the voltage conversion unit 50 to receive the voltage Vref, and is grounded through the resistor R3. A ground terminal of the electronic switch Q is grounded through the resistor R2.

In use, the south bridge 10 detects which type of DRAM is assembled on the computer motherboard 300 through the multiplexer 20. When the detected result is that the DRAMs 200 are DDR DRAMs, the south bridge 10 outputs a first signal to the CPLD 30. The CPLD 30 outputs a first control signal to the control terminal of the electronic switch Q to turn on the electronic switch Q, according to the first signal. The resistor R2 is connected to the voltage conversion unit 50 through the electronic switch Q, and the resistors R2 and R3 are connected in parallel. The relationship of the resistance r of the resistance unit 60, a resistance r2 of the resistor R2, and a resistance r3 of the resistor R3 is r=(r2×r3)/(r2+r3). The voltage Vout input into the DRAMs 200 is 2.5V, that is, the voltage adjustment circuit 100 provides 2.5V voltage to the DRAMs 200.

When the detected result is that the DRAMs 200 are DDR2 DRAMs, the south bridge 10 outputs a second signal to the CPLD 30. The CPLD 30 outputs a second control signal to the control terminal of the electronic switch Q to turn off the electronic switch Q, according to the second signal. The resistor R2 is disconnected from the voltage conversion unit 50. Resistance r of the resistance unit 60 is equal to a resistance r3 of the resistor R3, that is, r=r3. The voltage Vout input into the DRAMs 200 is 1.8V, that is, the voltage adjustment circuit 100 provides 1.8V voltage to the DRAMs 200. In the embodiment, the electronic switch Q is an n-channel metal-oxide semiconductor field-effect transistor (NMOSFET), the control terminal, the power terminal, and the ground terminal of the electronic switch Q are a gate, a drain, and a source of the NMOSFET, respectively.

In other embodiments, if there is a single DRAM 200 positioned on the motherboard 300, the multiplexer 20 can be omitted. If the DRAMs 200 are DDR3 DRAMs or other types DRAMs, in order to provide proper voltage to the DDR3 DRAMs or other types DRAMs, the number of the electronic switches Q and an equal number of resistors R2 included in the resistance unit 60 should be adjusted according to actual need. If the number of the electronic switch Q and the resistor R2 are increased, a control terminal of each electronic switch Q is connected to the CPLD 30 to receive the control signal, a power terminal of each electronic switch Q is connected to the voltage conversion unit 50 to receive the voltage Vref, the power terminal of each electronic switch Q is also grounded through the resistor R3, and a ground terminal of each electronic switch Q is grounded through a corresponding resistor R2. Each electronic switch Q may be a p-channel MOSFET, or a transistor, or other switch having similar functions.

The foregoing description of the exemplary embodiments of the disclosure has been presented only for the purposes of illustration and description and is not intended to be exhaustive or to limit the disclosure to the precise forms disclosed. Many modifications and variations are possible. The embodiments were chosen and described in order to explain the principles of the disclosure and their practical application so as to enable others of ordinary skill in the art to utilize the disclosure and various embodiments and with such modifications as are suited to the particular use contemplated. Alternative embodiments will become apparent to those of ordinary skills in the art to which the present disclosure pertains without departing from its spirit and scope. Accordingly, the scope of the present disclosure is defined by the appended claims rather than by the foregoing description and the exemplary embodiments described therein.

What is claimed is:

1. A voltage adjustment circuit used to adjust voltage output to a plurality of dynamic random access memories (DRAMs) assembled on a computer motherboard, according to a type of the DRAMs, the voltage adjustment circuit comprising:
a south bridge detecting the type of the DRAMs, and outputting a corresponding signal according to a detected result of the type of the DRAMs;
a complex programmable logic device (CPLD) connected to the south bridge, and outputting a corresponding control signal according to the signal;
a power supply unit;
a voltage conversion unit connected to the power supply unit, and connected to the DRAMs through a first resistor, wherein the voltage conversion unit converts voltage output from the power supply unit into a stable voltage; and
a resistance unit connected to the CPLD and the voltage conversion unit;
wherein the resistance unit provides different resistance according to the control signal received from the CPLD, and adjusts the stable voltage output from the voltage conversion unit to an operation voltage of the DRAMs.

2. The voltage adjustment circuit of claim 1, further comprising a multiplexer connected between the south bridge and the DRAMs, wherein the south bridge communicates with the DRAMs through the multiplexer.

3. The voltage adjustment circuit of claim 2, wherein the south bridge comprises a data pin and a clock pin, each DRAM comprises a data pin and a clock pin, the data pins and the clock pins of the south bridge and each DRAM are connected to the multiplexer, the south bridge detects the type of the DRAMs, according to information received from the data pins and the clock pins of the DRAMs.

4. The voltage adjustment circuit of claim 1, wherein the resistance unit comprises at least one electronic switch, at least one second resistor, and a third resistor, a number of the electronic switches equals to a number of the second resistors, and wherein each electronic switch comprises:
a control terminal connected to the CPLD;
a power terminal connected to an output of the voltage conversion unit that outputs the stable voltage, and grounded through the third resistor; and
a ground terminal grounded through a corresponding second resistor.

5. The voltage adjustment circuit of claim 4, wherein each electronic switch is an n-channel metal-oxide-semiconductor field-effect transistor (NMOSFET), the control terminal, the power terminal, and the ground terminal of each electronic switch are a gate, a drain, and a source of the NMOSFET, respectively.

6. A computer motherboard, comprising:
a plurality of dynamic random access memories (DRAMs); and
a voltage adjustment circuit comprising:
a south bridge detecting the type of the DRAMs, and outputting a corresponding signal according to a detected result of the type of the DRAMs;
a complex programmable logic device (CPLD) connected to the south bridge and outputting a corresponding control signal according to the signal;
a power supply unit;
a voltage conversion unit connected to the power supply unit, and connected to the DRAMs through a first resistor, wherein the voltage conversion unit converts voltage output from the power supply unit into a stable voltage; and
a resistance unit connected to the CPLD and the voltage conversion unit;
wherein the resistance unit provides different resistance according to the control signal received from the CPLD, and adjusts the stable voltage output from the voltage conversion unit to an operation voltage of the DRAMs.

7. The computer motherboard of claim 6, wherein the voltage adjustment circuit further comprises a multiplexer connected between the south bridge and the DRAMs, the south bridge communicates with the DRAMs through the multiplexer.

8. The computer motherboard of claim 7, wherein the south bridge comprises a data pin and a clock pin, each DRAM comprises a data pin and a clock pin, the data pins and the clock pins of the south bridge and each DRAM are connected to the multiplexer, the south bridge detects the type of the DRAMs, according to information received from the data pins and the clock pins of the DRAMs.

9. The computer motherboard of claim 6, wherein the resistance unit comprises at least one electronic switch, at least one second resistor, and a third resistor, a number of the electronic switches equals to a number of the second resistors, and wherein each electronic switch comprises:
a control terminal connected to the CPLD;
a power terminal connected to an output of the voltage conversion unit that outputs the stable voltage, and grounded through the third resistor; and
a ground terminal grounded through a corresponding second resistor.

10. The computer motherboard of claim 9, wherein each electronic switch is a metal-oxide-semiconductor field-effect transistor (MOSFET), the control terminal, the power terminal, and the ground terminal of each electronic switch are a gate, a drain, and a source of the MOSFET, respectively.
